(19) United States
(12) Patent Application Publication
(10) Pub. No.: US 2010/0003473 A1
(43) Pub. Date: Jan. 7, 2010

(54) METHOD FOR PRODUCING ORIGINAL MASTER USED TO PRODUCE MOLD STRUCTURE, ORIGINAL MASTER AND METHOD FOR PRODUCING MOLD STRUCTURE

(75) Inventor: Katsuhiro NISHIMAKI, Odawara-shi (JP)

Correspondence Address: YOUNG & THOMPSON, 209 Madison Street, Suite 500, Alexandria, VA, 22314, US

(73) Assignee: FUJIFILM Corporation, Tokyo (JP)

(21) Appl. No.: 12/497,100

(22) Filed: Jul. 2, 2009

(30) Foreign Application Priority Data
Jul. 2, 2008 (JP) 2008-173470

(51) Int. Cl. B32B 5/00; G03F 7/20

(52) U.S. Cl. 428/195.1; 430/323

(57) ABSTRACT

A method for producing an original master used to produce a mold structure, the method including: forming a resist layer on a surface of an original master substrate, and exposing and developing the resist layer so as to form on the surface of the substrate an original master resist pattern substantially in the shape of concentric arcs utilized to form an original master concavo-convex pattern; selectively etching the resist pattern, under one of a condition that the resist pattern on an inner circumferential side is etched to a greater extent than the resist pattern on an outer circumferential side and a condition that the resist pattern on the outer circumferential side is etched to a greater extent than the resist pattern on the inner circumferential side; and etching the substrate with the selectively etched resist pattern serving as a mask so as to form the original master concavo-convex pattern.

### BACKGROUND OF THE INVENTION

1. Field of the Invention

The present invention relates to a method for producing an original master used to produce a mold structure used to produce a magnetic recording medium such as a discrete track medium or patterned medium; an original master obtained by the method; and a method for producing a mold structure using the original master.

2. Description of the Related Art

In recent years, as magnetic recording media capable of high-density recording, note has been taken of discrete track media and patterned media.

In each discrete track medium, there are nonmagnetic regions provided between adjacent tracks, thereby magnetically separating the tracks from one another. Thus, the discrete track medium is characterized in that even when the space between each track is narrowed to increase recording density, magnetic interference (crosstalk) between the adjacent tracks can be reduced by the nonmagnetic regions.

Meanwhile, each patterned medium includes bits for signal recording which are arranged at regular intervals. The patterned medium is characterized in that even when the space between each bit is narrowed to increase recording density, the patterned medium is not much subject to heat fluctuation, since the bits are independent of one another.

Both the discrete track media and the patterned media have concavo-convex patterns on their surfaces. Such magnetic recording media having respective concavo-convex patterns (magnetic recording concavo-convex patterns) on their surfaces are produced using mold structures having, on their surfaces, respective concavo-convex patterns (mold concavo-convex patterns) which are inversions of the above-mentioned concavo-convex patterns (refer to Japanese Patent Application Laid-Open (JP-A) No. 2004-221465). Here, the mold structures are produced using original masters having, on their surfaces, respective concavo-convex patterns (original master concavo-convex patterns) formed based upon predetermined patterns designed with an electron beam writing apparatus, etc.

In the production of each magnetic recording medium, the concavo-convex pattern (mold concavo-convex pattern) of each mold structure is pressed against a resist layer formed on a surface of a magnetic layer, and a resist pattern is thus formed on the surface of the magnetic layer. Thereafter, the surface of the magnetic layer is etched with the resist pattern serving as a mask, and a concavo-convex pattern (magnetic recording concavo-convex pattern) is thus formed on the surface of the magnetic layer.

On each of the original masters used to produce the discrete track media or the patterned media, a plurality of convex portions having the same shape and corresponding to tracks or bits are concentrically disposed at regular intervals.

When light exposure or electron beam exposure is employed to obtain a resist pattern for forming such convex portions (concavo-convex pattern), the resist pattern may gradually narrow from the outer side toward the central side, or conversely, the resist pattern may gradually widen from the outer side toward the central side, depending upon exposure conditions. It is inferred that this is, for example, because of a difference in shrinkage rate between the resist pattern on the outer side and the resist pattern on the central side, which is caused by a difference between the time for which the former is left to stand and the time for which the latter is left to stand after exposure.

If a concavo-convex pattern of an original master is formed utilizing a resist pattern like this, there is such a problem that although a plurality of convex portions having the same shape are intended to be disposed at predetermined intervals, e.g. regular intervals, these convex portions are unevenly spaced.

A mold structure produced using such an original master, and a magnetic recording medium, e.g. a discrete track medium, produced using the mold structure are inferior in processing accuracy and thus problematic.

JP-A No. 2006-286121 proposes a master carrier used to magnetically transfer servo signals to servo areas of a magnetic recording medium; this master carrier has on its surface a concavo-convex pattern corresponding to the servo signals. In JP-A No. 2006-286121, slight variations in pattern line width among produced molds, each of which is used to produce the master carrier, are regarded as a problem; however, variations in pattern width regarding a single mold are not dealt with as a problem.

### BRIEF SUMMARY OF THE INVENTION

An object of the present invention is to provide an original master having an original master concavo-convex pattern in which convex portions are spaced less unevenly, a method for producing the original master, and a method for producing a mold structure using the original master.

Means for solving the problems are as follows.
<1> A method for producing an original master used to produce a mold structure having a mold concavo-convex pattern for forming an imprint resist pattern as a mask utilized to form a magnetic recording concavo-convex pattern in producing a magnetic recording medium having the magnetic recording concavo-convex pattern composed of a plurality of independent convex portions to be magnetically recorded and concave portions placed between each convex portion, arranged substantially in the shape of concentric arcs, the method including:

forming a resist layer on a surface of an original master substrate, and exposing and developing the resist layer so as to form on the surface of the original master substrate an original master resist pattern substantially in the shape of concentric arcs which is utilized to form an original master concavo-convex pattern,

selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side, and

etching the original master substrate with the selectively etched original master resist pattern serving as a mask so as to form the original master concavo-convex pattern.
<2> The method according to <1>, wherein the selectively etching further includes measuring a concave portion pattern width of the formed original master resist pattern, and selectively etching the original master resist pattern based upon a result of the measurement.
<3> The method according to <2>, wherein the measuring is measuring at least a concave portion width of the original master resist pattern on the innermost circumferential side and the concave portion width of the original master resist pattern on the outermost circumferential side.
<4> The method according to <1>, wherein the selectively etching is selectively etching the original master resist pattern based upon previously obtained data concerning a relationship between an etching time and an increased amount of a concave portion pattern width of the original master resist pattern.

In the method according to <4>, it is possible to select an appropriate trimming condition by previously obtaining a trimming rate distribution (as shown in FIG. 7 or 8, for example) used for the selectively etching.
<5> An original master including:

an original master substrate, and

an original master concavo-convex pattern disposed on a surface of the original master substrate, the original master concavo-convex pattern being substantially in the shape of concentric arcs and being an inversion of a mold concavo-convex pattern,

wherein a ratio of a concave portion width of the original master concavo-convex pattern on the outermost circumferential side to the concave portion width of the original master concavo-convex pattern on the innermost circumferential side is in the range of 0.9:1 to 1.1:1, and

wherein the original master is produced by a method for producing an original master used to produce a mold structure having the mold concavo-convex pattern for forming an imprint resist pattern as a mask utilized to form a magnetic recording concavo-convex pattern in producing a magnetic recording medium having the magnetic recording concavo-convex pattern composed of a plurality of independent convex portions to be magnetically recorded and concave portions placed between each convex portion, arranged substantially in the shape of concentric arcs, the method including forming a resist layer on the surface of the original master substrate, and exposing and developing the resist layer so as to form on the surface of the original master substrate an original master resist pattern substantially in the shape of concentric arcs which is utilized to form the original master concavo-convex pattern; selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side; and etching the original master substrate with the selectively etched original master resist pattern serving as a mask so as to form the original master concavo-convex pattern.
<6> A method for producing a mold structure, including:

pressing an original master against an imprint resist layer so as to transfer an original master concavo-convex pattern of the original master into the imprint resist layer applied onto a surface of a substrate to be processed,

curing the imprint resist layer; and

etching the surface of the substrate with the cured imprint resist layer serving as a mask so as to form a mold concavo-convex pattern on the surface of the substrate,

wherein the original master includes an original master substrate, and the original master concavo-convex pattern disposed on a surface of the original master substrate, the original master concavo-convex pattern being substantially in the shape of concentric arcs and being an inversion of the mold concavo-convex pattern,

wherein a ratio of a concave portion width of the original master concavo-convex pattern on the outermost circumferential side to the concave portion width of the original master concavo-convex pattern on the innermost circumferential side is in the range of 0.9:1 to 1.1:1, and

wherein the original master is produced by a method for producing an original master used to produce a mold structure having the mold concavo-convex pattern for forming an imprint resist pattern as a mask utilized to form a magnetic recording concavo-convex pattern in producing a magnetic recording medium having the magnetic recording concavo-convex pattern composed of a plurality of independent convex portions to be magnetically recorded and concave portions placed between each convex portion, arranged substantially in the shape of concentric arcs, the method including forming a resist layer on the surface of the original master substrate, and exposing and developing the resist layer so as to form on the surface of the original master substrate an original master resist pattern substantially in the shape of concentric arcs which is utilized to form the original master concavo-convex pattern; selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side; and etching the original master substrate with the selectively etched original master resist pattern serving as a mask so as to form the original master concavo-convex pattern.

In the method of the present invention for producing an original master used to produce a mold structure, since an original master resist pattern substantially in the shape of concentric arcs which is provided on a surface of an original master substrate is selectively etched under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side, it is possible to reduce variation in the pattern width of the original master resist pattern, and thus obtain an original master having an original master concavo-convex pattern with reduced variation in the space between each convex portion by etching the original master substrate using the selectively etched original master resist pattern as a mask.

According to the present invention, it is possible to solve the problems in related art and provide an original master having an original master concavo-convex pattern with reduced variation in the space between each convex portion, a method for producing the original master, and a method for producing a mold structure using the original master.

### BRIEF DESCRIPTION OF THE DRAWINGS

FIG. 1 is a plan view schematically showing an original master.

FIG. 2 is an explanatory drawing of a concavo-convex pattern of an original master used to produce a discrete track medium.

FIG. 3 is an explanatory drawing of a concavo-convex pattern of an original master used to produce a patterned medium.

FIGS. 4A to 4F are explanatory drawings together showing a process of producing an original master.

FIGS. 5A to 5E are explanatory drawings together showing a process of producing a mold structure.

FIGS. 6A to 6D are explanatory drawings together showing a process of producing a magnetic recording medium.

FIG. 7 is an explanatory diagram showing trimming rates regarding Example 1.

FIG. 8 is an explanatory diagram showing trimming rates regarding Example 2.

### DETAILED DESCRIPTION OF THE INVENTION

### [Original Master]

An original master of the present invention is used to produce a mold structure which has a concavo-convex pattern (mold concavo-convex pattern) corresponding to an imprint resist pattern utilized to form a magnetic recording concavo-convex pattern of a magnetic recording medium such as a discrete track medium or bit patterned medium.

The original master includes an original master substrate, and an original master concavo-convex pattern substantially in the shape of concentric arcs which is formed on a surface of the original master substrate and which is an inversion of the mold concavo-convex pattern. The original master substrate is a Si substrate or the like.

The following explains the original master of the present invention, referring to an original master according to an embodiment.

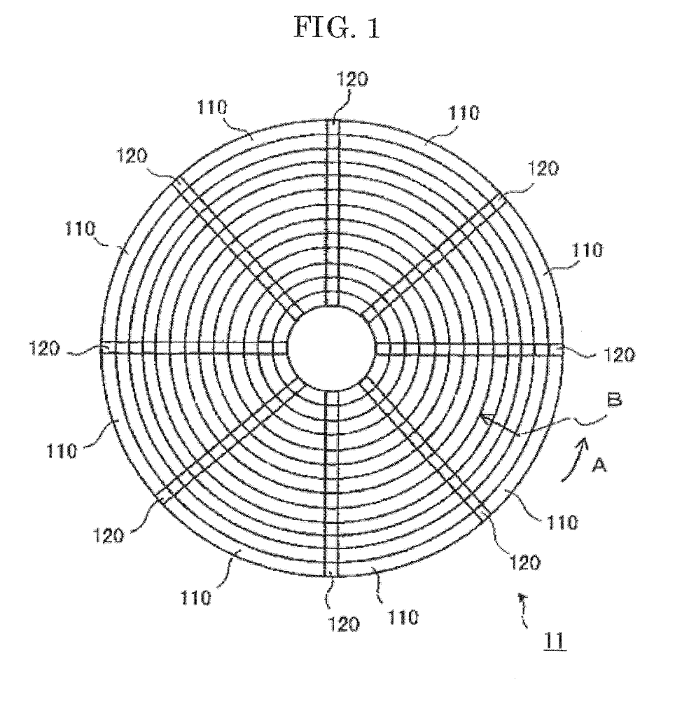

FIG. 1 is a plan view schematically showing an original master. In FIG. 1, the arrow shown by the letter A (arrow A) represents a circumferential direction of an original master 11, and the arrow shown by the letter B (arrow B) represents a radius direction of the original master 11.

Shaped like a disc, the original master 11 according to the present embodiment has, on its surface, at least a concavo-convex pattern 110 corresponding to data areas of the magnetic recording medium, and a concavo-convex pattern 120 corresponding to servo areas of the magnetic recording medium.

In the present embodiment, the term “original master concavo-convex pattern” is related to the concavo-convex pattern 110 corresponding to the data areas (hereinafter referred to as “original master concavo-convex pattern 110”).

The original master concavo-convex pattern 110 is arranged substantially in the shape of concentric arcs on the surface of the original master 11 (on the surface of an original master substrate). The original master concavo-convex pattern 110 includes convex portions and concave portions.

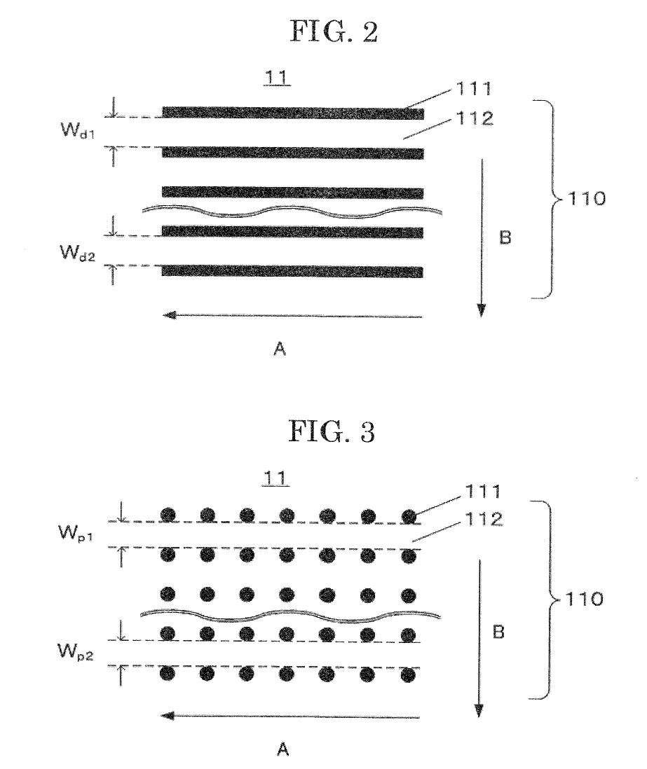

FIG. 2 is an explanatory drawing of an original master concavo-convex pattern 110 of an original master used to produce a discrete track medium (DTM). The original master concavo-convex pattern 110 shown in FIG. 2 is formed substantially in the shape of concentric arcs.

The original master concavo-convex pattern 110 shown in FIG. 2 includes convex portions 111 corresponding to magnetic portions (magnetic recording convex portions) of a magnetic recording medium (discrete track medium), and concave portions 112 corresponding to nonmagnetic portions of the magnetic recording medium.

The convex portions 111 are linear portions extending in the circumferential direction of the original master, and they are substantially rectangular in cross section with respect to the radius direction of the original master. The convex portions 111 are disposed substantially in the shape of concentric arcs with respect to the radius direction. The concave portions 112 are spaces formed between the adjacent convex portions 111.

FIG. 3 is an explanatory drawing of an original master concavo-convex pattern 110 of an original master used to produce a patterned medium. The original master concavo-convex pattern 110 shown in FIG. 3 is formed substantially in the shape of concentric arcs.

The original master concavo-convex pattern 110 shown in FIG. 3 includes convex portions 111 corresponding to magnetic portions (magnetic recording convex portions) of a magnetic recording medium (patterned medium), and concave portions 112 corresponding to nonmagnetic portions of the magnetic recording medium.

The convex portions 111 shown in FIG. 3 are substantially in the shape of columns and are disposed in the circumferential direction of the original master. Also, the convex portions 111 are disposed in the radius direction of the original master as well. The convex portions 111 are substantially rectangular in cross section with respect to the radius direction.

### [Method for Producing Original Master]

A method of the present invention for producing an original master used to produce a mold structure includes a step of forming an original master resist pattern, a selective etching step and a step of forming an original master concavo-convex pattern and, if necessary, includes other step(s).

The step of forming an original master resist pattern is a step of forming a resist layer on a surface of an original master substrate, and exposing and developing the resist layer so as to form on the surface of the original master substrate an original master resist pattern substantially in the shape of concentric arcs which is utilized to form an original master concavo-convex pattern.

The selective etching step is a step of selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side.

It should be noted that the selective etching step in the present invention is intended to etch the original master resist pattern primarily but is not intended to etch the original master substrate greatly.

The step of forming an original master concavo-convex pattern is a step of etching the original master substrate with the selectively etched original master resist pattern serving as a mask so as to form an original master concavo-convex pattern.

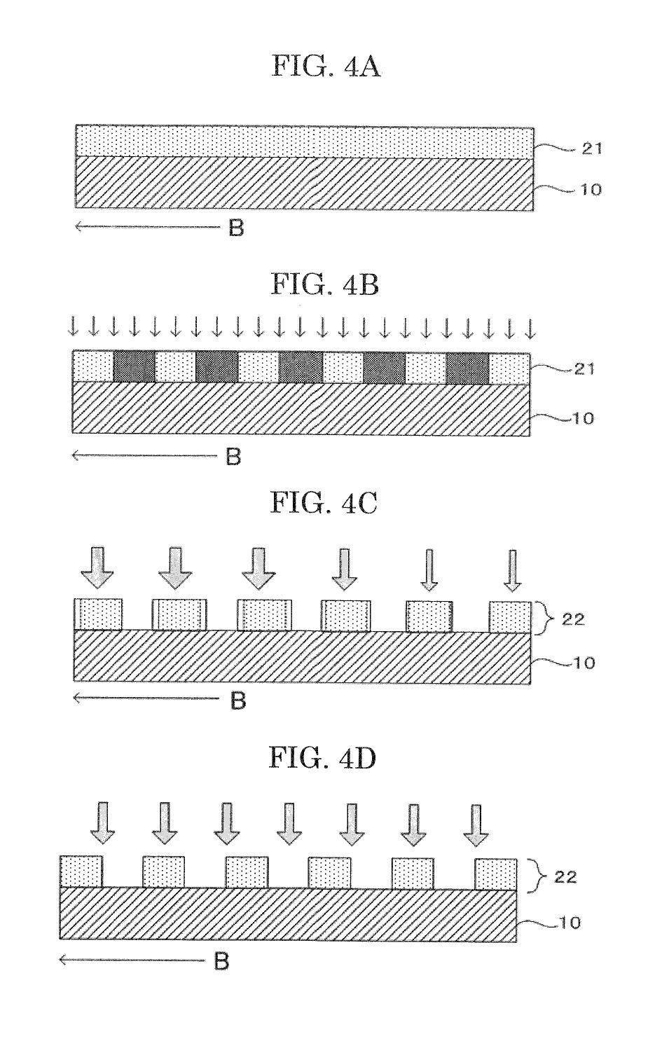

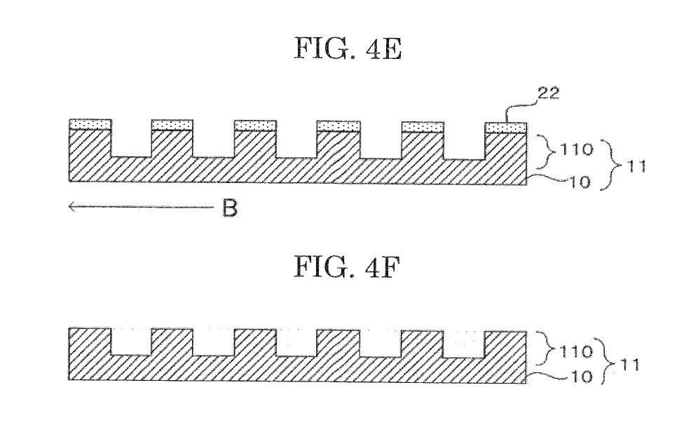

The following explains an embodiment of a method for producing an original master used to produce a mold structure, referring to FIGS. 4A to 4F. FIGS. 4A to 4F are explanatory drawings (cross-sectional views) together showing a process of producing an original master.

### <Step of Forming Original Master Resist Pattern>

As shown in FIG. 4A, a resist solution is applied onto a disc-shaped Si substrate (original master substrate) 10 by spin coating or the like so as to form a resist layer 21. In each of FIGS. 4A to 4F, the arrow B represents a radius direction of the original master substrate 10, and the arrow B is directed toward the central side of the original master substrate 10.

Thereafter, while rotating the substrate 10 with the resist layer 21 formed thereon, the resist layer 21 is exposed to laser light (or an electron beam) modulated correspondingly to a magnetic recording concavo-convex pattern.

Thereafter, the resist layer 21 is developed, the exposed portions are removed, and a pattern 22 formed by the resist layer 21 (an original master resist pattern 22) is thus obtained (see FIGS. 4B and 4C).

### <Selective Etching Step>

In the present embodiment, as shown in FIG. 4C, the concave portion pattern width of the original master resist pattern 22 on the outer circumferential side is greater than that of the original master resist pattern 22 on the inner circumferential side.

The selective etching step is a step of etching the resist pattern 22 having different concave portion pattern widths, such that the resist pattern 22 has a uniform concave portion pattern width with respect to the radius direction. In FIG. 4C, the arrow B is directed toward the inner circumferential side.

In the present embodiment, to make the resist pattern 22 have a uniform concave portion pattern width with respect to the radius direction, the resist pattern 22 is subjected to etching such as reactive ion etching (RIE) under a condition that convex portions in the resist pattern 22 on the inner circumferential side are etched to a greater extent than convex portions in the resist pattern 22 on the outer circumferential side. The selectively etched resist pattern 22 has a uniform concave portion pattern width with respect to the radius direction, as shown in FIG. 4D.

In another embodiment, when the concave portion pattern width of an original master resist pattern on the inner circumferential side is greater than that of the original master resist pattern on the outer circumferential side, it is appropriate to etch the resist pattern under a condition that the resist pattern on the outer circumferential side is etched to a greater extent than the resist pattern on the inner circumferential side.

Etching conditions (trimming conditions), for example gas(es) used for the etching, the pressure and the electrical power, may be decided without any limitation in particular and suitably selected according to the purpose.

For instance, the etching conditions may be decided based upon a result of measuring the concave portion pattern width of an original master resist pattern using a measuring device such as a CD-SEM (critical dimension scanning electron microscope).

Also, the etching conditions may be decided based upon previously obtained data concerning a relationship between an etching time and an increased amount of the concave portion pattern width of an original master resist pattern.

When the concave portion pattern width of an original master resist pattern is measured using a predetermined measuring device, it is appropriate, for example, to measure the concave portion width of the original master resist pattern in at least two different positions with respect to the radius direction.

In this case, it is particularly preferable to measure the concave portion width of the resist pattern on the innermost circumferential side and the concave portion width of the resist pattern on the outermost circumferential side.

As to variation in the concave portion pattern width of an original master resist pattern with respect to the radius direction, there is a case where it gradually increases from the inner circumferential side to the outer circumferential side, and conversely there is another case where it gradually increases from the outer circumferential side to the inner circumferential side.

Accordingly, for example, the result of a measurement of the concave portion width of the resist pattern on the innermost circumferential side and the concave portion width of the resist pattern on the outermost circumferential side makes it possible to understand which of the resist pattern on the inner circumferential side and the resist pattern on the outer circumferential side needs to be etched to a greater extent.

For example, the etching conditions may be decided based upon the measured difference between the concave portion width of the resist pattern on the innermost circumferential side and that of the resist pattern on the outermost circumferential side.

### <Step of Forming Original Master Concavo-Convex Pattern>

As shown in FIG. 4D, the Si substrate (original master substrate) 10 is etched, with the selectively etched original master resist pattern 22 serving as a mask. For this etching, a known etching method may be employed such as RIE. Etching conditions are appropriately set such that the substrate 10 is etched uniformly with respect to the radius direction.

After this etching, an original master concavo-convex pattern 110 is formed on the surface of the substrate 10 (see FIGS. 4E and 4F), and an original master 11 is thus obtained. Additionally, the residual mask (resist pattern 22) is appropriately removed (see FIG. 4E).

### [Pattern Width of Original Master Concavo-convex Pattern of Original Master]

Regarding an original master produced by the method of the present invention for producing an original master, an original master concavo-convex pattern has uniform pattern widths (convex portion pattern width and concave portion pattern width) with respect to the radius direction, and thus variation in the pattern widths of the concavo-convex pattern with respect to the radius direction can be reduced.

According to the method of the present invention for producing an original master, the ratio of the concave portion width of the original master concavo-convex pattern on the outermost circumferential side to the concave portion width of the original master concavo-convex pattern on the innermost circumferential side (outermost circumferential concave portion width/innermost circumferential concave portion width) can be in the range of 0.9:1 to 1.1:1.

Note that the original master of the present invention is an original master wherein the ratio (outermost circumferential concave portion width/innermost circumferential concave portion width) is in the range of 0.9:1 to 1.1:1.

Here, the ratio of the outer circumferential concave portion pattern width to the inner circumferential concave portion pattern width is further explained, giving as examples a case of an original master used to produce a discrete track medium and a case of an original master used to produce a patterned medium.

As described above, an original master used to produce a discrete track medium has an original master concavo-convex pattern 110 as shown in FIG. 2.

In FIG. 2, the symbol W_{d1} denotes the concave portion width of the concavo-convex pattern on the outermost circumferential side (outermost circumferential concave portion width) with respect to the radius direction, and the symbol W_{d2} denotes the concave portion width of the concavo-convex pattern on the innermost circumferential side (innermost circumferential concave portion width) with respect to the radius direction.

In this case, the ratio (outermost circumferential concave portion width/innermost circumferential concave portion width) can be expressed as W_{d1}/W_{d2}. According to the method of the present invention for producing an original master, the value of W_{d1}/W_{d2} can be in the range of 0.9 to 1.1.

As described above, an original master used to produce a patterned medium has an original master concavo-convex pattern 110 as shown in FIG. 3.

In FIG. 3, the symbol Wₚ₁ denotes the concave portion width of the concavo-convex pattern on the outermost circumferential side (outermost circumferential concave portion width) with respect to the radius direction, and the symbol Wₚ₂ denotes the concave portion width of the concavo-convex pattern on the innermost circumferential side (innermost circumferential concave portion width) with respect to the radius direction.

In this case, the ratio (outermost circumferential concave portion width/innermost circumferential concave portion width) can be expressed as Wₚ₁/Wₚ₂.

According to the method of the present invention for producing an original master, the value of Wₚ₁/Wₚ₂ can be in the range of 0.9 to 1.1.

### [Method for Producing Mold Structure]

A method of the present invention for producing a mold structure includes producing a mold structure using an original master produced by the method of the present invention for producing an original master. The following explains the method of the present invention for producing a mold structure, referring to a method for producing a mold structure according to an embodiment.

The method for producing a mold structure according to the present embodiment includes a transferring step, a curing step and a pattern forming step and, if necessary, includes other step(s). The transferring step is a step of pressing the above-mentioned original master against an imprint resist layer so as to transfer the original master concavo-convex pattern of the original master into the imprint resist layer applied onto a surface of a substrate to be processed. The curing step is a step of curing the imprint resist layer. The pattern forming step is a step of etching the surface of the substrate with the cured imprint resist layer serving as a mask so as to form a mold concavo-convex pattern on the surface of the substrate.

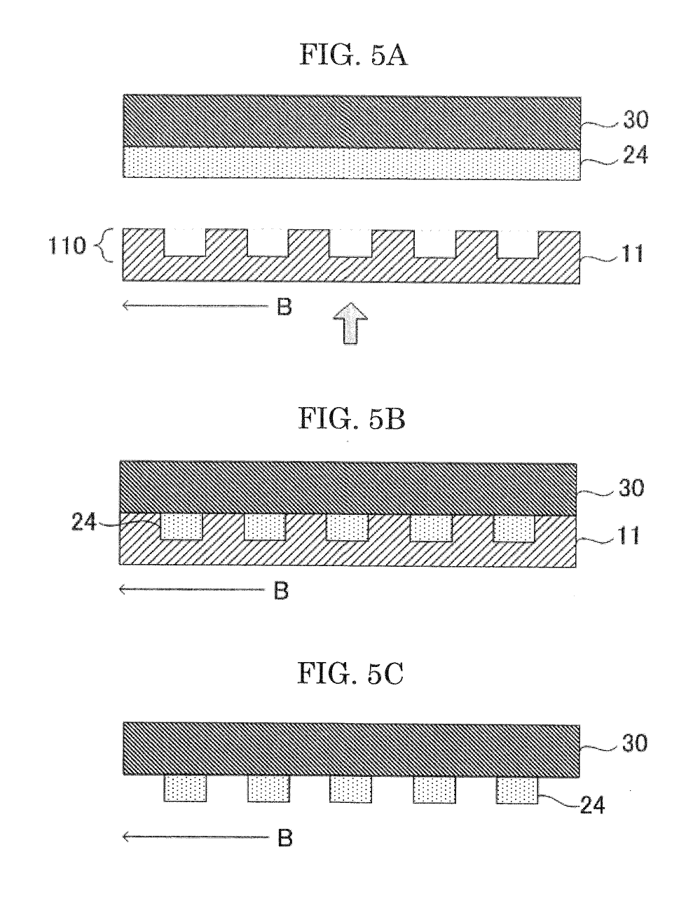

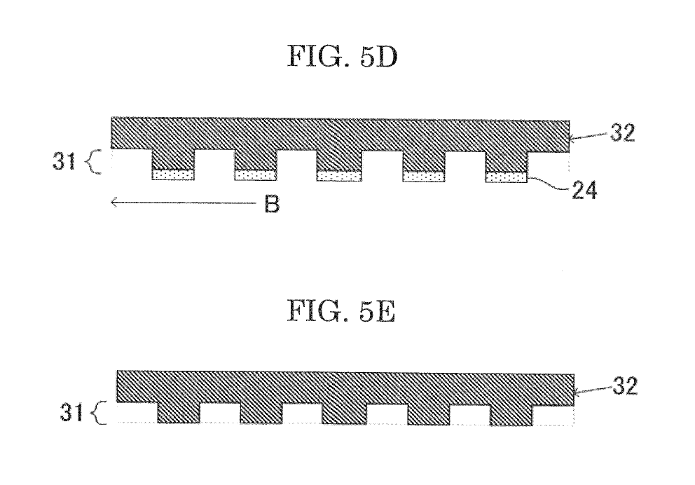

FIGS. 5A to 5E are explanatory drawings together showing a process of producing a mold structure. The following explains the method for producing a mold structure according to the present embodiment, referring to FIGS. 5A to 5E.

### <Transferring Step>

As shown in FIG. 5A, the original master 11 is pressed against an imprint resist layer 24 formed by applying an imprint resist solution containing a photocurable resin onto a surface of a substrate 30 to be processed (a quartz substrate), and the original master concavo-convex pattern 110 of the original master 11 is thus transferred into the imprint resist layer 24 (see FIG. 5B).

In the present embodiment, the material for the substrate 30 is not particularly limited as long as it has such strength as can function as a mold structure, and the material is suitably selected according to the purpose. Examples thereof include quartz (SiO₂) and organic resins (PET, PEN, polycarbonates, low-melting-point fluorine resins, etc.).

### <Curing Step>

After the transferring step, the imprint resist layer 24 is irradiated with an ultraviolet ray or the like to cure the imprint resist layer 24 (see FIG. 5C). The cured imprint resist layer 24 forms an inverted pattern of the original master concavo-convex pattern 110.

### <Pattern Forming Step>

After the curing step, the substrate 30 is subjected to etching such as RIE with the cured imprint resist layer 24 serving as a mask (see FIG. 5D), such that a mold concavo-convex pattern 31 is formed on the surface of the substrate 30, and a mold structure 32 is thus obtained (see FIG. 5E). Additionally, the residual mask (imprint resist layer 24) is appropriately removed.

In a method for producing a mold structure according to another embodiment, a mold structure may be produced by performing Ni electroforming, using the original master 11 as a matrix.

### [Method for Producing Magnetic Recording Medium]

A method of the present invention for producing a magnetic recording medium includes producing a magnetic recording medium using a mold structure produced by the method of the present invention for producing a mold structure.

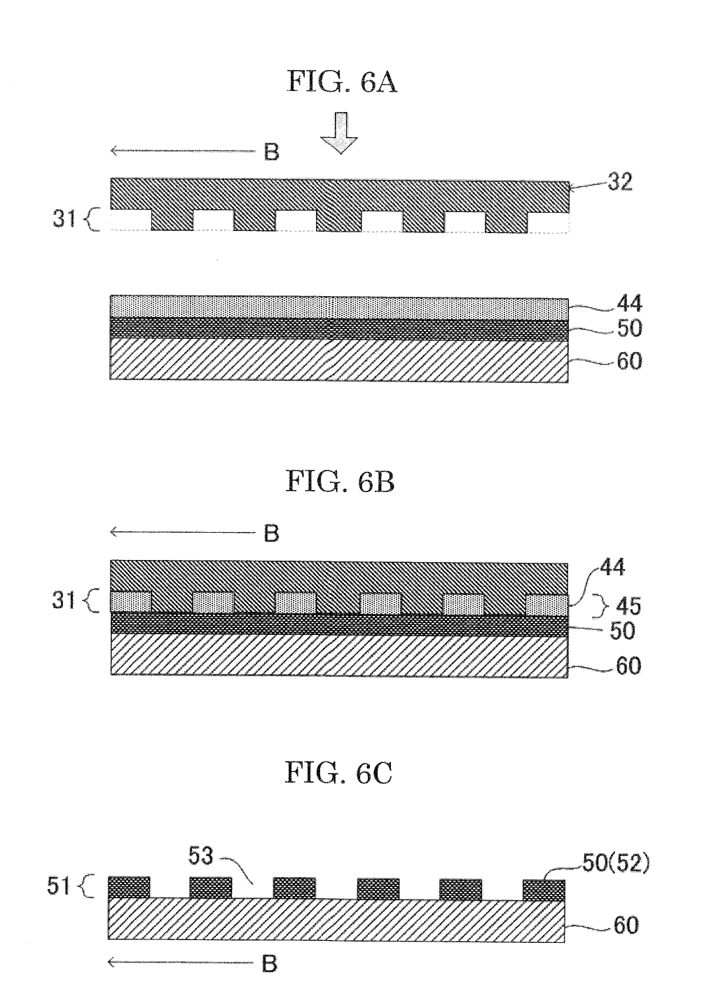

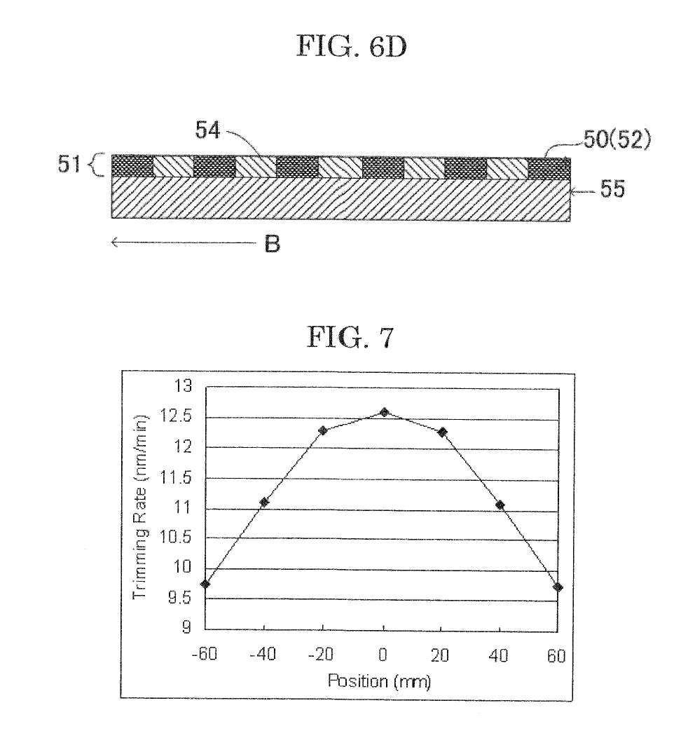

The following explains a method for producing a magnetic recording medium according to an embodiment, referring to FIGS. 6A to 6D. FIGS. 6A to 6D are explanatory drawings (cross-sectional views) together showing a process of producing a magnetic recording medium. In the present embodiment, the mold structure produced by the above-mentioned method for producing a mold structure is used.

As shown in FIG. 6A, there is prepared a substrate 60 for a magnetic recording medium, that is covered, in the order mentioned, with a magnetic layer 50, and an imprint resist layer 44 formed by applying an imprint resist solution of PMMA or the like. By pressing the mold structure 32 against the imprint resist layer 44 applied over the substrate 60 (see FIG. 6B), the mold concavo-convex pattern 31 of the mold structure 32 is transferred into the imprint resist layer 44, and an imprint resist pattern 45 is thus formed (secondary transferring step).

The imprint resist pattern 45 may be thermally cured or photocured. The imprint resist solution is suitably selected according to how the pattern is cured, for example.

Thereafter, the magnetic layer 50 is subjected to etching such as RIE, using the imprint resist pattern 45 as a mask, and a magnetic recording concavo-convex pattern 51 composed of the magnetic layer 50 is formed on the substrate 60 as shown in FIG. 6C (step of forming a magnetic recording concavo-convex pattern). The magnetic recording concavo-convex pattern 51 includes a plurality of independent magnetic recording convex portions 52 (formed by the magnetic layer 50) arranged substantially in the shape of concentric arcs.

Further, as shown in FIG. 6D, concave portions 53 are filled with a nonmagnetic material 54, then the surface is flattened, and a magnetic recording medium 55 is thus obtained. If necessary, the magnetic recording medium 55 may be provided with a protective film and/or the like.

Note that the magnetic recording convex portions 52 are magnetic portions provided independently of one another in the form of protrusions in a magnetic recording medium such as a discrete track medium or bit patterned medium.

### EXAMPLES

The following explains Examples of the present invention. It should, however, be noted that the present invention is not confined to these Examples in any way.

### Example 1

### [Production of Original Master]

An original master was produced by the process of producing an original master, shown in FIGS. 4A to 4F. The original master was an original master used to produce a discrete track medium. The following explains the production of the original master in detail.

### <Step of Forming Original Master Resist Pattern>

A disc-shaped 8-inch Si substrate (original master substrate) 10 was prepared. A resist solution (FEP-171, produced by FUJIFILM Electronic Materials Co., Ltd.) was applied onto this original master substrate 10 by spin coating so as to form a resist layer 21.

Thereafter, while rotating the substrate 10 with the resist layer 21 formed thereon, the resist layer 21 was exposed to an electron beam corresponding to a predetermined pattern. Here, the exposure was carried out from the outer circumferential side toward the inner circumferential side of the substrate. The electron beam writing took 20 hours.

Subsequently, the resist layer 21 was developed, the exposed portions were removed, and an original master resist pattern 22 was thus obtained.

Regarding the original master resist pattern 22 obtained, the TPI (track per 5 inch: the number of tracks per inch) was 170,000.

### <Selective Etching Step>

Next, the concave portion pattern width of the resist pattern 22 on the substrate 10 with respect to the radius direction was measured. For this measurement, a CD-SEM (S9380, manufactured by Hitachi High-Technologies Corporation) was used.

Measurement targets were the resist pattern 22 on the innermost circumferential side and the resist pattern 22 on the outermost circumferential side.

As a result of the measurement, the concave portion width of the resist pattern 22 on the innermost circumferential side was 52 nm, and the concave portion width of the resist pattern 22 on the outermost circumferential side was 59 nm.

Exposure conditions were set such that the resist pattern 22 had a uniform concave portion pattern width with respect to the radius direction.

Trimming conditions (RIE conditions) for the resist pattern 22 were decided based upon the result of the measurement. The trimming conditions were as follows.

### <Trimming Conditions>

Gas used: O₂ (100 sccm), CF₄ (10 sccm)
Pressure: 12 Pa
ICP power: 30 W
Bias power: 0 W

The selective etching step was carried out under the above conditions, such that convex portions in the resist pattern 22 on the inner circumferential side were etched to a greater extent than convex portions in the resist pattern 22 on the outer circumferential side.

FIG. 7 is an explanatory diagram showing trimming rates in the selective etching step. The vertical axis represents the trimming rate (nm/min) of the resist pattern 22 etched in the selective etching step, and the horizontal axis represents the distance (mm) from the center of the substrate.

The trimming rate was calculated by measuring the length of the space (concave portion) between adjacent convex portions in the resist pattern 22.

As shown in FIG. 7, it has been confirmed that the resist pattern was etched such that the extent of etching increased from the outer circumferential side toward the central side (inner circumferential side) of the substrate.

Examples of means for adjusting the distribution of trimming rates include altering the plasma density distribution by increasing or decreasing the ICP power, and altering the plasma density distribution by changing the outer diameter and/or thickness of ring-shaped part(s) placed in the vicinity of a lower electrode (wafer stage) of an etching device.

The substrate was etched, using as a mask the resist pattern 22 trimmed in the selective etching step. For the etching of the substrate, a mixed gas of fluorocarbon gas and Ar gas was used.

Hollows were formed in the substrate by the etching, and an original master having an original master concavo-convex pattern was thus obtained. Additionally, the mask (resist pattern 22) remaining on the surface of the original master concavo-convex pattern was removed by oxygen plasma ashing.

### <Evaluation>

The ratio (outermost circumferential concave portion width/innermost circumferential concave portion width) regarding the original master obtained was calculated. The result showed W_{d1}/W_{d2}=1.08.

### Comparative Example 1

An original master was produced in the same manner as in Example 1, except that the selective etching step was not carried out.

### <Evaluation>

The ratio (outermost circumferential concave portion width/innermost circumferential concave portion width) regarding the original master obtained was calculated as in Example 1. The result showed W_{d1}/W_{d2}=1.15.

### Example 2

An original master was produced in the same manner as in Example 1, except that the original master resist pattern was etched under the following trimming conditions (RIE conditions) in the selective etching step.

As a result, it was possible to etch convex portions in the resist pattern 22 on the outer circumferential side to a greater extent than convex portions in the resist pattern 22 on the inner circumferential side.

### <Trimming Conditions>

Gas used: O₂ (100 sccm), CF₄ (5 sccm)
Pressure: 10 Pa
ICP power: 100 W
Bias power: 0 W

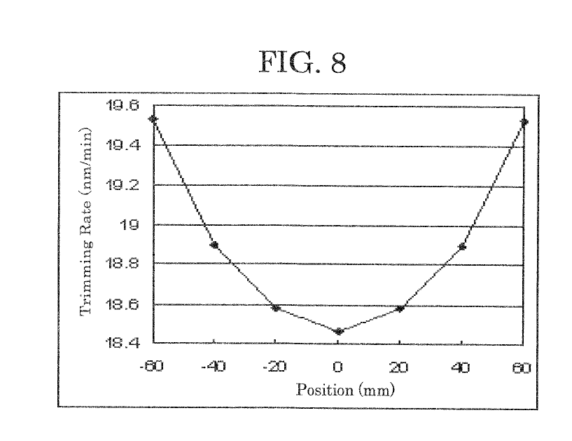

FIG. 8 is an explanatory diagram showing trimming rates regarding Example 2.

The vertical axis represents the trimming rate (nm/min) of the original master resist pattern etched, and the horizontal axis represents the distance (mm) from the center of the substrate. The trimming rate was calculated by measuring the length of the space (concave portion) between adjacent convex portions in the resist pattern.

As shown in FIG. 8, it has been confirmed that the resist pattern was etched such that the extent of etching increased from the central side (inner circumferential side) toward the outer circumferential side of the substrate.

Therefore, as to the concave portion pattern width of the resist pattern on the substrate, when the pattern width on the inner circumferential side was greater than that on the outer circumferential side, convex portions in the resist pattern on the outer circumferential side were able to be etched to a greater extent than convex portions in the resist pattern on the inner circumferential side by setting the trimming rates as in Example 2.

### <Evaluation>

The ratio (outermost circumferential concave portion width/innermost circumferential concave portion width) regarding the original master obtained was calculated. The result showed W_{d1}/W_{d2}=1.09.

What is claimed is:

1. A method for producing an original master used to produce a mold structure having a mold concavo-convex pattern for forming an imprint resist pattern as a mask utilized to form a magnetic recording concavo-convex pattern in producing a magnetic recording medium having the magnetic recording concavo-convex pattern composed of a plurality of independent convex portions to be magnetically recorded and concave portions placed between each convex portion, arranged substantially in the shape of concentric arcs, the method comprising:
forming a resist layer on a surface of an original master substrate, and exposing and developing the resist layer so as to form on the surface of the original master substrate an original master resist pattern substantially in the shape of concentric arcs which is utilized to form an original master concavo-convex pattern,
selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side, and
etching the original master substrate with the selectively etched original master resist pattern serving as a mask so as to form the original master concavo-convex pattern.

2. The method according to claim 1, wherein the selectively etching further comprises measuring a concave portion pattern width of the formed original master resist pattern, and selectively etching the original master resist pattern based upon a result of the measurement.

3. The method according to claim 2, wherein the measuring is measuring at least a concave portion width of the original master resist pattern on the innermost circumferential side and the concave portion width of the original master resist pattern on the outermost circumferential side.

4. The method according to claim 1, wherein the selectively etching is selectively etching the original master resist pattern based upon previously obtained data concerning a relationship between an etching time and an increased amount of a concave portion pattern width of the original master resist pattern.

5. An original master comprising:
an original master substrate, and
an original master concavo-convex pattern disposed on a surface of the original master substrate, the original master concavo-convex pattern being substantially in the shape of concentric arcs and being an inversion of a mold concavo-convex pattern,
wherein a ratio of a concave portion width of the original master concavo-convex pattern on the outermost circumferential side to the concave portion width of the original master concavo-convex pattern on the innermost circumferential side is in the range of 0.9:1 to 1.1:1, and
wherein the original master is produced by a method for producing an original master used to produce a mold structure having the mold concavo-convex pattern for forming an imprint resist pattern as a mask utilized to form a magnetic recording concavo-convex pattern in producing a magnetic recording medium having the magnetic recording concavo-convex pattern composed of a plurality of independent convex portions to be magnetically recorded and concave portions placed between each convex portion, arranged substantially in the shape of concentric arcs, the method comprising forming a resist layer on the surface of the original master substrate, and exposing and developing the resist layer so as to form on the surface of the original master substrate an original master resist pattern substantially in the shape of concentric arcs which is utilized to form the original master concavo-convex pattern; selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side; and etching the original master substrate with the selectively etched original master resist pattern serving as a mask so as to form the original master concavo-convex pattern

6. A method for producing a mold structure, comprising:
pressing an original master against an imprint resist layer so as to transfer an original master concavo-convex pattern of the original master into the imprint resist layer applied onto a surface of a substrate to be processed,
curing the imprint resist layer; and
etching the surface of the substrate with the cured imprint resist layer serving as a mask so as to form a mold concavo-convex pattern on the surface of the substrate,
wherein the original master comprises an original master substrate, and the original master concavo-convex pattern disposed on a surface of the original master substrate, the original master concavo-convex pattern being substantially in the shape of concentric arcs and being an inversion of the mold concavo-convex pattern,
wherein a ratio of a concave portion width of the original master concavo-convex pattern on the outermost circumferential side to the concave portion width of the original master concavo-convex pattern on the innermost circumferential side is in the range of 0.9:1 to 1.1:1, and
wherein the original master is produced by a method for producing an original master used to produce a mold structure having the mold concavo-convex pattern for forming an imprint resist pattern as a mask utilized to form a magnetic recording concavo-convex pattern in producing a magnetic recording medium having the magnetic recording concavo-convex pattern composed of a plurality of independent convex portions to be magnetically recorded and concave portions placed between each convex portion, arranged substantially in the shape of concentric arcs, the method comprising forming a resist layer on the surface of the original master substrate, and exposing and developing the resist layer so as to form on the surface of the original master substrate an original master resist pattern substantially in the shape of concentric arcs which is utilized to form the original master concavo-convex pattern; selectively etching the original master resist pattern, under one of a condition that the original master resist pattern on an inner circumferential side is etched to a greater extent than the original master resist pattern on an outer circumferential side and a condition that the original master resist pattern on the outer circumferential side is etched to a greater extent than the original master resist pattern on the inner circumferential side; and etching the original master substrate with the selectively etched original master resist pattern serving as a mask so as to form the original master concavo-convex pattern.
